(19) United States
(12) Patent Application Publication
(10) Pub. No.: US 2024/0402238 A1
(43) Pub. Date: Dec. 5, 2024

(54) TEST SYSTEM AND METHOD FOR DATA VERIFICATION FOR THE SAME

(71) Applicant: MPI CORPORATION, Hsinchu County (TW)

(72) Inventors: Andrej Rumiantsev, Hsinchu County (TW); LIN-LIN CHIH, Hsinchu County (TW); CHING-LING PAI, Hsinchu County (TW)

(21) Appl. No.: 18/327,021

(22) Filed: May 31, 2023

(51) Int. Cl. G01R 31/265; G01R 35/00

(52) U.S. Cl. CPC G01R 31/2656; G01R 35/005

(57) ABSTRACT

A test system and a method for data verification for the same are provided. The test system includes a main control unit having a control host and an analyzer, and a probe assembly that includes at least one probe-head with probe tips and a cable linked to the analyzer. The probe assembly is configured to contact one of testing circuits of a calibration standard assembly via the probe tips for performing a calibration process. In the method, incident data is inputted to the calibration standard assembly for generating measured uncorrected data, and afterwards the measured uncorrected data can be verified by performing relative comparison on any two sets of the measured uncorrected data.

### FIELD OF THE DISCLOSURE

The present disclosure relates to data verification for a test system, and more particularly to a method for performing data verification based on a relative comparison of outputs of testing circuits in order to make sure that the test system can output an accurate measurement result.

### BACKGROUND OF THE DISCLOSURE

In the related art, a test system including one or more radio-frequency (RF) probes and related circuit components is generally used to test electrical characteristics such as properties of radio frequency of a device under test (DUT). For example, the test system can be an automated device that is implemented by collaboration of hardware and software in order to perform an electrical test, especially the test of RF characteristics, of a semiconductor device such as RF transistors, RF passive components, RF and Millimeter-Wave (mm Wave) Integrated Circuit or switched, etc. However, every RF probe has its own RF properties and the inherent RF properties will impact the measurement performed by the test system. Therefore, it is an important issue how to reduce the impact caused by the inherent electrical characteristics of the test system.

In certain approaches of the conventional technology, for example, shielding elements can be placed in between the circuit components of the test system or form any shielding structure in order to reduce the impact of RF signals on the measurement result produced by the test system. Further, when the impact of measurement error can be quantified, the measurement result of the test system can be compensated numerically.

### SUMMARY OF THE DISCLOSURE

In order to provide accurate and reliable measurement results of a test system, rather than the conventional approaches, the present disclosure provides a method for data verification and a test system that performs the method for it is acknowledged that the data generated by the test system should be verified in order to make sure the test system can use the correct data.

In one aspect of the test system that performs the method for data verification, the test system includes a main control unit including a control host and an analyzer, and a probe assembly having at least one probe-head with one or more probe tips and at least one cable linked to the analyzer via one or more ports. The test system provides a calibration standard assembly, and the probe assembly is configured to contact one of testing circuits of the calibration standard assembly via the one or more probe tips for performing a calibration process with incident data generated by the control host.

The mentioned testing circuits are mounted on a calibration substrate, and configured to be contacted by one or more probe tips of at least one probe assembly of the test system.

Further, in the method for data verification performed by the test system, the main control unit inputs incident data to the calibration standard assembly having the two or more testing circuits, and then obtains a measured uncorrected data by measuring the incident data through the two or more testing circuits. The measured uncorrected data can be verified by performing relative comparison on any two sets of the measured uncorrected data outputted from at least two of the testing circuits of the calibration standard assembly. It should be noted that any one of the testing circuits is selected as a reference circuit and another one of the testing circuits is selected as the testing circuit outputting the measured uncorrected data to be verified.

Moreover, a result of the relative comparison is configured to compare with a verification boundary setting for verifying the measured uncorrected data. The verification boundary setting is adjustable and can be illustrated by a series of thresholds over frequencies or a range between an upper-limit line and a lower-limit line over frequencies.

Before the measured uncorrected data is verified, the method further comprises a step of verifying the measured uncorrected data by comparing with a raw data boundary setting, and the raw data boundary setting can also be adjustable and illustrated by a series of thresholds over frequencies or a range between an upper-limit line and a lower-limit line over frequencies.

Specifically, the two or more testing circuits are selected from a group essentially consisting of an AIR testing circuit, an OPEN testing circuit, a SHORT testing circuit, a LOAD testing circuit, a THROUGH testing circuit and a LINE testing circuit. The measured uncorrected data is produced based on a corresponding standard measurement which is selected from an AIR standard, an OPEN standard, a SHORT standard, a LOAD standard, a THROUGH standard and a LINE standard.

In the test system, under a reflection mode, the analyzer processes signals received by at least one port via a signal terminal and a ground terminal of the at least one probe-head of the probe assembly; further, under a transmission mode, the analyzer processes the signals received by two or more ports via signal terminals and ground terminals of the at least one probe-head of the probe assembly.

Further, the measured uncorrected data contains a series of frequency responses that relate to electrical characteristics of the probe assembly of the test system and can be expressed in phases or magnitudes (alternatively normalized phases or magnitude) over frequencies. More, the series of frequency responses can be expressed by a frequency response diagram displayed on a display device of the control host.

The verification boundary setting that can be used to verify the measured uncorrected data is introduced. The verification boundary setting can be illustrated by a series of threshold as a boundary line shown in the frequency response diagram over frequencies or a range between an upper-limit line and a lower-limit line shown in the frequency response diagram over frequencies.

It should be noted that the boundary line, the upper-limit line and the lower-limit line are adjustable via a computer-implemented adjustment tool on the frequency response diagram. Further, the boundary line, the upper-limit line or the lower-limit line can have only one segment with a set of boundary values or have multiple segments with different sets of boundary values.

Still further, before the steps of the method for data verification, repeatability verification can be performed for testing stability of the test system. In an aspect of the repeatability verification, the repeatability verification includes firstly inputting, via the probe assembly of the test system, the data to the calibration standard assembly, and then repeatedly measuring uncorrected data through the two or more testing circuits of the calibration standard assembly. The repeatability of the measured uncorrected data can therefore be verified by comparing a difference between any two of the repeatedly-measured uncorrected data with a repeatability boundary setting.

Further, in the method for data verification, the control host calculates a compensation data that is used to compensate measurement of the control host by comparing an ideal dataset with the verified measured uncorrected data. In particular, the compensation data is provided for compensating a next measured uncorrected data so as to obtain an error term verification dataset. The compensation data can be verified if a difference between the error term verification dataset and the ideal dataset is within a model data boundary setting.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram illustrating a test system and its peripherals according to one embodiment of the present disclosure;

FIG. 2A is a schematic view of a calibration substrate having the testing circuits according to one embodiment of the present disclosure;

FIG. 2B to FIG. 2D are top views of exemplary probe tips having multiple conductors shown measuring SHORT, LOAD and AIR standards respectively;

FIG. 3 is a flowchart illustrating a process of verifying the data measured by the test system according to one embodiment of the present disclosure;

FIG. 4 is a flowchart illustrating a process of verifying repeatability of the measured uncorrected data according to one embodiment of the present disclosure;

FIG. 5 is a flowchart illustrating steps of the method for data verification in the test system according to one embodiment of the present disclosure;

FIG. 6 is a schematic diagram depicting a concept of operation of the test system that performs the method for data verification according to one embodiment of the present disclosure;

FIG. 7 is a flowchart illustrating a process of error term verification in the method for data verification according to one embodiment of the present disclosure;

FIG. 8 is one further schematic diagram depicting a concept of operation of the test system according to one further embodiment of the present disclosure;

FIG. 9A shows a frequency reference diagram depicting non-normalized magnitudes of S11-AIR, S11-OPEN, S22-AIR and S22-OPEN parameters in certain examples;

FIG. 9B is a schematic diagram of a frequency response diagram that provides two boundary lines for differences of S11 and S22 parameters with respect to AIR standard and OPEN standard magnitude measurements in certain examples;

FIG. 10 is another schematic diagram of a frequency response diagram that provides two boundary lines for differences of S11 and S22 parameters with respect to OPEN standard and SHORT standard phase measurements according to another embodiment of the present disclosure;

FIG. 11A shows a frequency response diagram in non-normalized phases of S11-AIR, S11-OPEN, S22-AIR and S22-OPEN parameters in certain examples;

FIG. 11B is one further schematic diagram of a frequency response diagram in normalized phases that provides two boundary lines for differences of S11 and S22 parameters with respect to AIR standard and OPEN standard phase measurements in certain examples;

FIG. 12 is still one further schematic diagram of a frequency response diagram that shows a boundary line for differences of S11 and S22 parameters with respect to OPEN standard and LOAD standard magnitude measurements according to one further embodiment of the present disclosure;

FIG. 13 is a schematic diagram of a frequency response diagram that provides two adjustable boundary lines for differences of S11 and S22 parameters according to one embodiment of the present disclosure;

FIG. 14 is one further schematic diagram of a frequency response diagram that provides four boundary lines for differences of S11 and S22 parameters according to one further embodiment of the present disclosure;

FIG. 15 is still one further schematic diagram of a frequency response diagram that provides two fixed boundary lines and two adjustable boundary lines for differences of S11 and S22 parameters according to one further embodiment of the present disclosure; and

FIG. 16 is a schematic diagram depicting a four-tip probe-head contacting with a calibration substrate in certain embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

For the inadequacies that the conventional technologies cannot guarantee that a source data provided for measuring electrical characteristics of a device under test (DUT) is correct, the present disclosure provides a test system and a method for verifying the correctness of the source data before the testing. For providing an accurate measurement while testing the DUT, the test system of the present disclosure is required to initially provide an accurate source data that has been verified through one or more verification processes. One of the objectives of the method for data verification performed by the test system is to verify the measured uncorrected data in order to make sure that the data generated by a main control unit of the test system is correct. One further objective of the method is to calculate an error term from the verified measured uncorrected data in order to compensate the measured uncorrected data based on a difference between an ideal dataset and the measured uncorrected data. It should be noted that the measured uncorrected data contains a series of frequency responses that relate to electrical characteristics of the probe assembly of the test system and are expressed in phases or magnitudes (alternatively normalized phases or magnitudes) over frequencies.

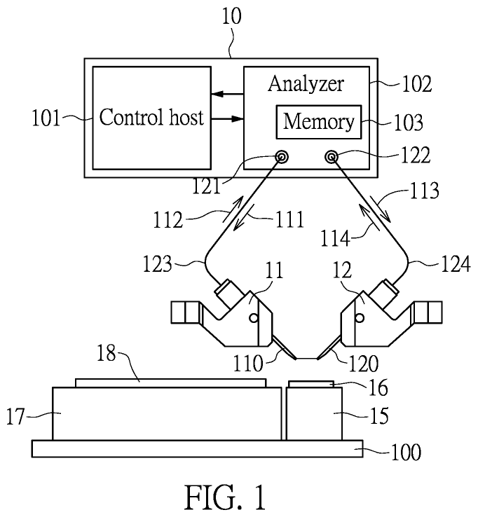

Reference is made to FIG. 1, which is a schematic diagram illustrating the test system and its peripherals according to one embodiment of the present disclosure.

The test system includes a main control unit 10 that is configured to control operations of the test system and especially produce the data for testing. The main control unit 10 essentially includes a computer-implemented control host 101 and an analyzer 102. The control host 101 acts as a system controller that is configured to produce the data to be tested and generate control commands for operating the analyzer 102. The control host 101 can communicate with the analyzer 102 and control the analyzer 102 through signals being transmitted over a signal line (e.g., a GPIB bus). In an aspect of the present disclosure, the analyzer 102 can be implemented by a vector network analyzer (VNA) with a source measure unit (SMU). The analyzer 102 can act as a signal generation and analysis assembly that is used to transmit data, receive measured data and conduct analysis upon the measurements.

According to one embodiment of the present disclosure, the control host 101 can be equipped with a display that is used to display a picture showing the operations of the test system or a diagram showing results of measurements. The display can be any device (e.g., LED display or LCD display of the control host 101) that is configured to show the operational progress of the test system. For example, the results of measurement can be shown via a graphical user interface (GUI) as a frequency response diagram showing magnitudes or phases of the frequency responses of the DUT.

For testing a device under test 18, as shown in the diagram, the analyzer 102 outputs the data being generated by the control host 101 via one or more ports to probe electrical characteristics of the device under test 18 placed on a main chuck 17. In general, the analyzer 102 outputs radio frequency (RF) test signals to the device under test 18 by a probe assembly, e.g., an RF probe assembly. The probe assembly includes at least one cable, at least one probe-head and one or more probe tips. In an exemplary example, as shown in the figure, the analyzer 102 provides a first port 121 that connects with a first probe-head 11 via a first cable 123 and a second port 122 that connects with a second probe-head 12 via a second cable 124.

One or more probe tips can be installed on the probe-head. The probe assembly includes at least one probe-head with one or more probe tips and at least one cable linked to the analyzer 102 via one or more ports (121, 122). The one or more probe tips are used to contact a calibration substrate of a calibration standard assembly 16 on a calibration chuck 15, and the data generated by the control host 101 can be transmitted to the calibration substrate and received from the calibration substrate via the one or more tips. As shown in the diagram, the first probe-head 11 includes one or more first probe tips 110, and the second probe-head 12 includes one or more second probe tips 120.

In one embodiment of the present disclosure, the analyzer 102 prepares a memory 103 used to store the data, which is passed through the analyzer 102, received by the analyzer 102 and provided to be transmitted to the calibration standard assembly 16. The data is such as a measured uncorrected data that can be the uncorrected data measured from the calibration substrate, an error term that is calculated by the control host 101, and a corrected data that has been compensated by the error term.

The test system should be calibrated with one or more calibration standards in order to provide accurate measurement before the test system is in operation of testing the electrical characteristics of the device under test 18 placed on the main chuck 17 on a machine table 100. In the present embodiment of the present disclosure, the calibration standard assembly 16 mounted on the calibration chuck 15 on the machine table 100 is prepared for calibrating the test system. One or more testing circuits are mounted on the calibration substrate of the calibration standard assembly 16. The probe assembly of the test system is configured to contact the one or more testing circuits via the one or more probe tips (110, 120) of the at least one probe assembly. By the probe assembly, the test system transmits the uncorrected data to the one or more testing circuits and then measures the uncorrected data received therefrom.

The test system can operate under a reflection mode and a transmission mode. Under the reflection mode, the analyzer 102 processes signals received by at least one port (121, 122) via a signal terminal and a ground terminal of the at least one probe-head (11, 12) of the probe assembly; and, under the transmission mode, the analyzer 102 processes the signals received by two or more ports (121, 122) via signal terminals and ground terminals of the at least one probe-head (11, 12) of the probe assembly.

For example, the control host 101 sends a command to the analyzer 102 for enabling the reflection mode, and under the reflection mode the analyzer 102 transmits an incident data 111 (or 113, i.e., an uncorrected data) generated by the control host 101 to the one or more testing circuits on the calibration substrate of the calibration standard assembly 16 via the first port 121 (or the second port 122), and then receives the measured uncorrected data 112 (or 114) via the same port, i.e., the first port 121 (or the second port 122). On the other hand, the control host 101 sends another command to the analyzer for enabling the transmission mode, and under the transmission mode the analyzer 102 transmits the incident data 11 to the one or more testing circuits via the first port 121, and then receives the measured uncorrected data 114 via another port, i.e., the second port 122.

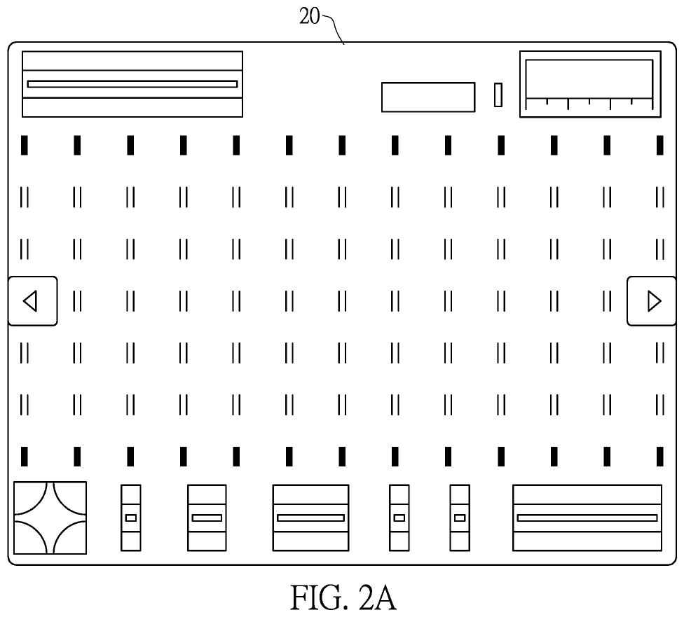

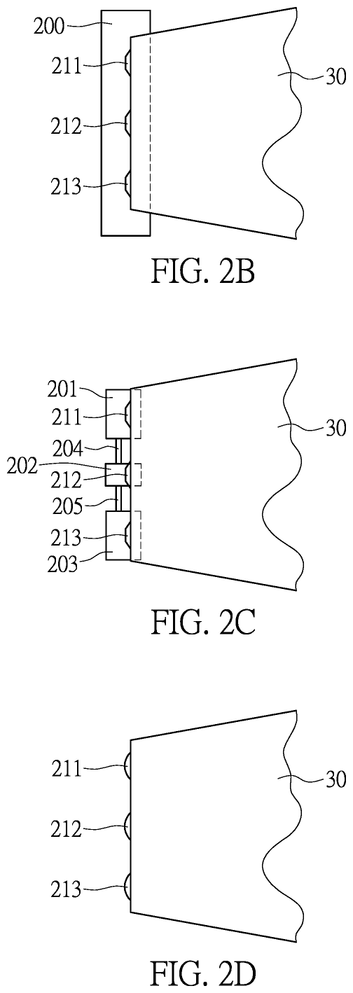

A calibration substrate 20 which is schematically shown in FIG. 2A is configured to provide the one or more testing circuits thereon. In one embodiment of the present disclosure, the calibration substrate 20 can be a printed circuit board involving one or more testing circuits made of multiple metal lines so as to arrange various testing circuits of standards. The metal lines include multiple electric pads. For achieving a relative comparison, two or more testing circuits on the calibration substrate 20 are required. The two or more testing circuits are selected from a group essentially consisting of an AIR testing circuit, an OPEN testing circuit, a SHORT testing circuit, a LOAD testing circuit, a THROUGH testing circuit and a LINE testing circuit. Accordingly, the above-described measured uncorrected data is produced based on a corresponding standard measurement which is selected from an AIR standard, an OPEN standard, a SHORT standard, a LOAD standard, a THROUGH standard and a LINE standard.

FIG. 2B to FIG. 2D optionally show the schematic diagrams of probe tips having multiple conductors with respect to SHORT, LOAD and AIR standards respectively.

More specifically, in certain embodiments of the present disclosure, the AIR testing circuit is configured to conduct testing through a pair of RF probes being lifted above the DUT at a distance for testing the electrical characteristics thereof.

FIG. 2B schematically shows a probe tip 30 that is formed as a coplanar waveguide type according to one embodiment of the present disclosure. The probe tip 30 of FIG. 2B includes multiple conductors 211, 212 and 213 that are arranged to correspond to the conductive pads of a SHORT testing circuit with respect to a SHORT standard.

In an exemplary example, the conductors (211, 212, 213) embody a first ground terminal 211, a signal terminal 212 and a second ground terminal 213 that are configured to contact a planar conductive strip 200 that is mounted on the calibration substrate 20, as shown in FIG. 2A, and allows the conductors 211, 212 and 213 of the probe tip 30 to contact the pads of the SHORT testing circuit in unison.

FIG. 2C is another schematic diagram depicting another probe tip 30 having multiple conductors 211, 212 and 213 according to one embodiment of the present invention. In the present embodiment, the conductors (211, 212, 213) also embody the first ground terminal 211, the signal terminal 212 and the second ground terminal 213. The conductors 211, 212 and 213 are configured to contact three conductive strips 201, 202 and 20 that are interconnected with resistors 204 and 205 (e.g., 100 ohm resistors) of a LOAD testing circuit with respect to a LOAD standard. Similarly, the conductive strips 201, 202 and 20 allow the conductors 211, 212 and 213 of the probe tip 30 to contact the pads of the LOAD testing circuit in unison.

FIG. 2D shows one further schematic diagram of the probe tip 30 having the conductors 211, 212 and 213 that do not contact with any testing circuit. In other words, the conductors 211, 212 and 213 are configured to be tested under an AIR standard.

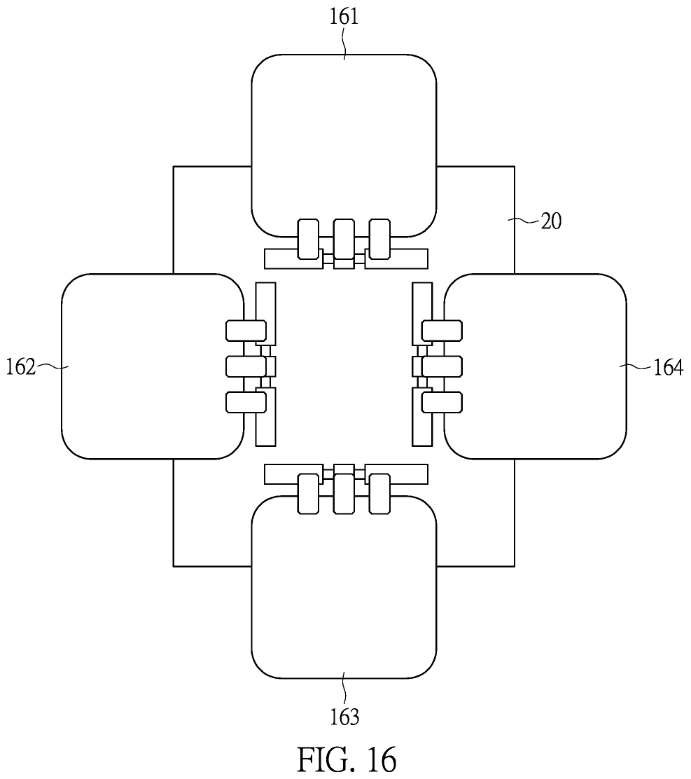

Furthermore, in certain embodiments of the present disclosure, the test system also supports multiple probes rather than the pair of RF probes described above. Reference is made to FIG. 16, which is a schematic diagram depicting a four-tip probe-head contacting with four testing circuits mounted on a calibration substrate.

For example, in FIG. 16, the calibration substrate provides multiple LOAD testing circuits, each of which includes several conductive strips that are interconnected via resistors. In the diagram, four probe-heads 161, 162, 163 and 164 for adapting to a four-probe test system are configured to contact with the four sets of conductive strips mounted on the calibration substrate respectively.

In an aspect of the present disclosure, the measured uncorrected data can be verified by performing the relative comparison on any two sets of the measured uncorrected data outputted from at least two of the testing circuits of the calibration standard assembly, in which two or more testing circuits are required for performing the relative comparison for data verification. The relative comparison requires calculating a difference between two results of standard measurements that can be any combination of the above-mentioned standards, for example, AIR-OPEN, AIR-SHORT, OPEN-SHORT, OPEN-THROUGH, OPEN-LOAD, SHORT-THROUGH, and SHORT-LOAD, etc.

For example, when the relative comparison of OPEN-SHORT standard measurements is performed, an OPEN dataset and a SHORT dataset are validated, and then a difference under a normalized phase or a normalized magnitude of the datasets can be calculated. After that, a result of the relative comparison is configured to compare with a verification boundary setting for verifying the measured uncorrected data. In particular, the verification boundary setting can be adjustable and can be illustrated by a series of thresholds over frequencies or a range between an upper-limit line and a lower-limit line over frequencies. It should be noted that, through the relative comparison, any problem such as bad contact, dead standard, broken probe, damaged cable, not-planarized probe, damaged analyzer port, or measured wrong standard of the test system can be recognized.

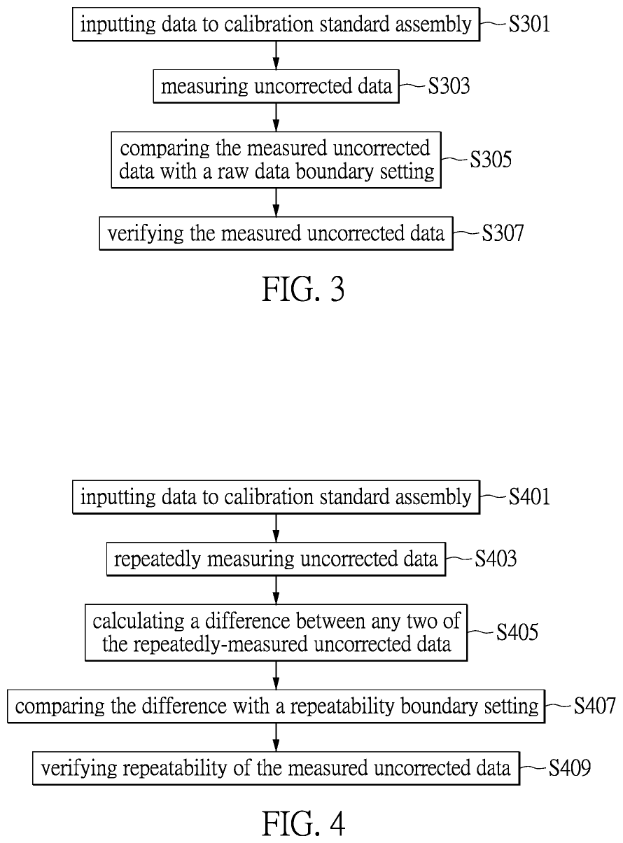

FIG. 3 is a flowchart illustrating a process of verifying the data measured by the test system before verifying the measured uncorrected data according to one embodiment of the present disclosure.

When the control host of the main control unit of the test system outputs the data for system calibration, the analyzer of the main control unit inputs the data to one of the testing circuits of the calibration standard assembly (step S301), and then measures the uncorrected data from the testing circuit (step S303).

For verifying the data, the system prepares a raw data boundary setting. The control host compares the measured uncorrected data with the raw data boundary setting (step S305) so as to verify the measured uncorrected data (step S307). It should be noted that the raw data boundary setting can be adjustable and can be illustrated by a series of thresholds over frequencies or a range between an upper-limit line and a lower-limit line over frequencies. If a difference between the measured uncorrected data and the raw data boundary setting exceeds a predetermined value, the data fails to be verified, but otherwise the data can be verified if the difference is within a predetermined range.

Still further, before data verification, repeatability verification is performed for testing stability of the test system and the repeatability verification. Reference is made to FIG. 4, which is a flowchart illustrating a process of verifying repeatability of the measured uncorrected data according to one embodiment of the present disclosure.

In the beginning, the analyzer inputs data to any of the testing circuits of the calibration standard assembly via the probe assembly of the test system (step S401), and repeatedly measures the uncorrected data received from the two or more testing circuits (step S403). It should be noted that the analyzer can repeat multiple measurements on the same testing circuit with respect to any of the standards. Therefore, the analyzer can receive multiple repeatedly-measured uncorrected data. After that, the control host can calculate a difference between any two of the repeatedly-measured uncorrected data (step S405).

The difference is then compared with a repeatability boundary setting that is pre-determined by the test system (step S407). It should be noted that the repeatability boundary setting can also be adjustable and can be illustrated by a series of thresholds over frequencies or a range between an upper-limit line and a lower-limit line over frequencies. The repeatability of the measured uncorrected data can be verified if a result of the comparison is within a specific range.

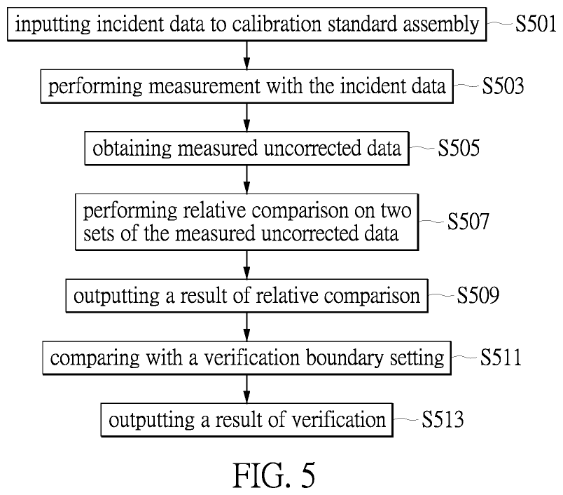

After the measured uncorrected data is verified and/or the repeatability of the measured uncorrected data is verified, the data inputted from the analyzer to the testing circuits is measured and is required to be verified. Reference is made to FIG. 5, which is a flowchart illustrating steps of the method for data verification in the test system according to one embodiment of the present disclosure.

The analyzer of the test system inputs the incident data to the calibration standard assembly having two or more testing circuits from the main control unit via a probe assembly (step S501). The incident data is inputted to any of the testing circuits mounted on the calibration substrate, and the analyzer then measures the data received from the testing circuit (step S503). The control host can obtain the measured uncorrected data by measuring the incident data through the two or more testing circuit (step S505), and performs a relative comparison on two sets of the measured uncorrected data outputted from at least two testing circuits of the calibration standard assembly (step S507).

The relative comparison is performed on any two sets of the measured uncorrected data outputted from at least two of the testing circuits of the calibration standard assembly, in which one of the testing circuits can be selected as a reference circuit and another one of the testing circuits can be selected as a second testing circuit other than the reference circuit. The measured uncorrected data outputted from the second testing circuit can be verified according to a difference there-between when comparing with the output of the reference circuit.

A result of the relative comparison is then outputted (step S509), and the result is compared with the above-mentioned verification boundary setting that is predetermined by the test system (step S511). The comparison between the result and the verification boundary setting indicates whether or not the data (i.e., the incident data) is verified (step S513).

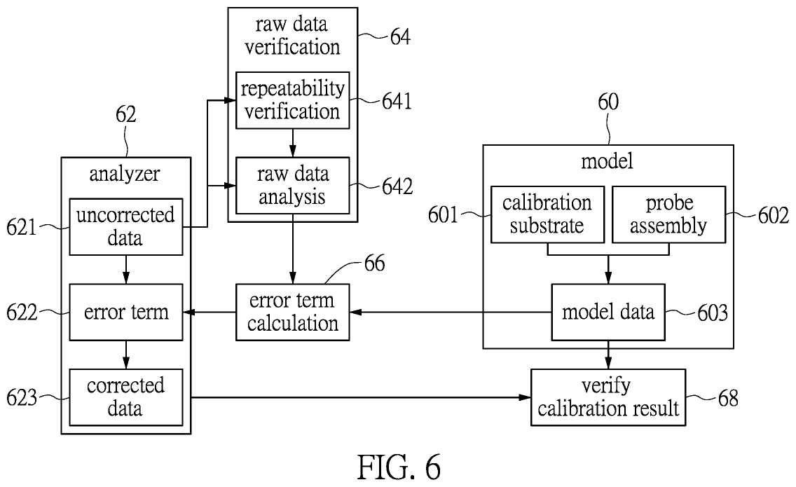

FIG. 6 is a schematic diagram depicting a concept of operation of the test system that performs the method for data verification according to one embodiment of the present disclosure.

For verifying the data generated by the test system for testing the device under test, the test system firstly defines an ideal dataset, i.e., a model 60. The test system defines a model data 603 based on the peripherals of the test system. The model data 603 acts as the ideal dataset being defined by considering the electrical characteristics of the peripherals such as a calibration substrate 601 having the testing circuits and a probe assembly 602 of the test system. For example, by referring to a data sheet of the calibration substrate 601 and RF characteristics of the probe assembly 602, the test system can determine the proper model data 603 as the ideal dataset for the test system to verify the data that is generally used for testing the device under test.

The analyzer 62 prepares an uncorrected data 621, an error term 622 and a corrected data 623 in its memory. When the analyzer 62 outputs uncorrected data to any of the testing circuits of the calibration standard assembly, and then the analyzer 62 can measure the outputs of the testing circuits so as to form the measured uncorrected data. For example, the measured uncorrected data is generally a testing result from an AIR testing circuit, an OPEN testing circuit, a SHORT testing circuit, a LOAD testing circuit, a THROUGH testing circuit or a LINE testing circuit, and the measured uncorrected data can be an AIR standard measurement, an OPEN standard measurement, a SHORT standard measurement, a LOAD standard measurement, a THROUGH standard measurement or a LINE standard measurement.

Before the test system is in operation, the test system performs raw data verification 64 including repeatability verification 641 and raw data analysis 642 for verifying the data outputted by the test system. The repeatability verification 641 can refer to the flowchart shown in FIG. 4.

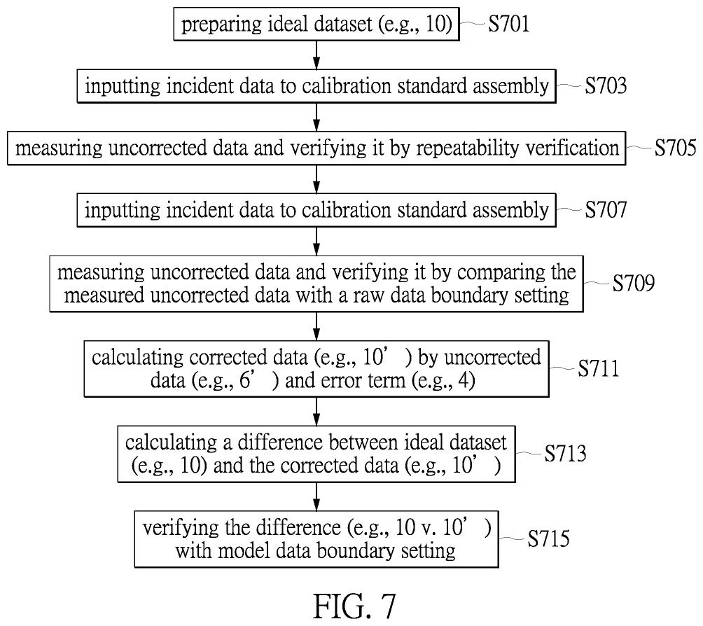

In an aspect of the present disclosure, the test system provides an error term verification mechanism to make sure of the correctness of the error term. When the error term (e.g. 10−6=4) is verified, the compensation data (e.g. 4) can be verified if a difference between the error term verification dataset (e.g. 10′) and the ideal dataset (e.g. 10) is within a model data boundary setting. Still further, the model data boundary setting being illustrated by a series of thresholds over frequencies or a range between an upper-limit line and a lower-limit line over frequencies can also be adjustable. Wherein, the error term verification dataset is based on the measured uncorrected data (e.g. 6′) to be compensated with the error term (e.g. 4). For more details refer to the description of FIG. 7.

According to one of the embodiments of the present disclosure, the test system provides adjustable boundary lines to set up the upper-limit and the lower-limit line. For example, the upper-limit line and the lower-limit line can be adjustable via a computer-implemented adjustment tool on the frequency response diagram. Further, the boundary line, the upper-limit line or the lower-limit line can have only one segment with a set of boundary values or have multiple segments with different sets of boundary values.

In certain embodiments, the adjustment tool can be a computer-implemented software function that is configured to adjust the boundary line(s). For example, the adjustment tool can be expressed as a symbol or an icon shown on a display having a touch panel that allows a user to touch for controlling the adjustment tool. Further, the user can also use other input methods (e.g., a computer mouse or a keyboard) to control the adjustment tool for adjusting a position and a length of any of the boundary lines.

For the error term verification, reference is made to FIG. 7, which is a flowchart illustrating a process of error term verification according to one embodiment of the present disclosure.

In FIG. 7, the model data 603 (e.g. 10) that acts as the ideal dataset is prepared (step S701). The test system inputs the incident data to the calibration standard assembly via the probe assembly (step S703), and the analyzer measures the uncorrected data (e.g. 6) received from the calibration standard assembly through any of the testing circuits, and in the meantime verifies the uncorrected data through repeatability verification (step S705). The control host then performs raw data analysis so as to calculate the compensation data (i.e., an error term (e.g., 4 which is to subtract 6 from 10)) between the ideal dataset (i.e., the model data 603 (e.g., 10)) and the measured uncorrected data (e.g., 6). Accordingly, the error term is verified if the difference between the ideal dataset (e.g., 10) and the corrected data (e.g., 10′) is within the model data boundary setting. The verified error term acts as the compensation data that can be applied to repeatability verification, applied to raw data verification/raw data analysis, or applied to data verification based on relative comparison, so that the measured uncorrected data can be well compensated with the verified error term.

In FIG. 7, again, the test system inputs another incident data to the calibration standard assembly (step S707). The analyzer also measures the uncorrected data (e.g., 6′) received from the calibration standard assembly with respect to a specific testing circuit, and verifies the uncorrected data through comparing the measured uncorrected data with the raw data boundary setting so as to verify the measured uncorrected data (step S709). After that, the corrected data (e.g., 10′) can be calculated according to the uncorrected data (e.g., 6′) and the error term (e.g., 4) that are calculated through the steps S701 to S709 by the control host (step S711). For verifying the error term, a difference between the ideal dataset (e.g., 10) and the corrected data (e.g., 10′) is calculated (step S713), and the difference that acts as the error term can be verified by comparing with the model data boundary setting (step S715).

Accordingly, if the error term has been verified, the test system can be calibrated with one or more calibration standards with the compensation data that is based on the correctness of the error term.

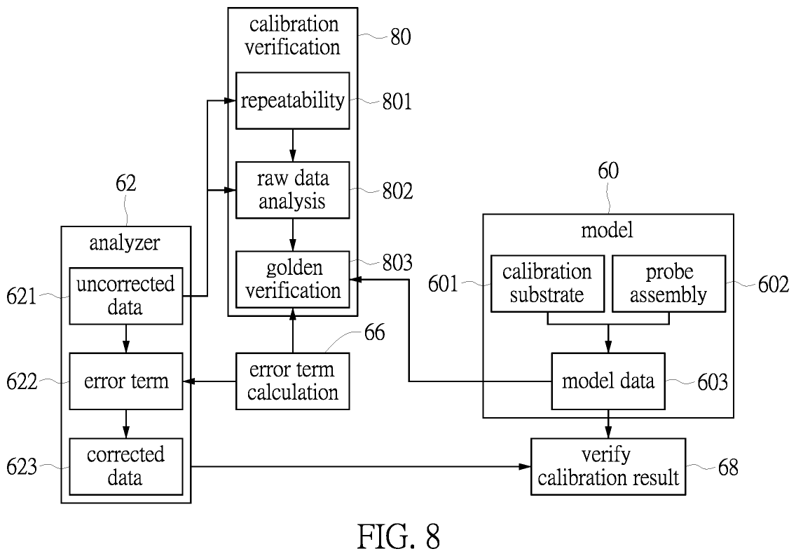

Besides the embodiment shown in FIG. 6, FIG. 8 is one further schematic diagram depicting a concept of operation of the test system according to one further embodiment of the present disclosure.

In FIG. 8, calibration verification 80 performed by the test system includes a repeatability verification (801), a raw data verification (802) and a golden verification 803 with the error term.

The test system firstly defines the model data 603 (for example, “10”) and then obtains the measured uncorrected data 621 (for example, “6”). The error term 622 (for example, 10−6=“4”) that is used for compensating the test system can be calculated based on the model data 603 and the measured uncorrected data 621.

When the error term (e.g. 4) is obtained, the error term acts as a compensation data for correcting the measured uncorrected data (for example, “6′”). However, the error term can still be verified through golden verification by comparing the error term verification dataset (i.e., 10′) and the ideal dataset (i.e., 10, the model data) in order to make sure of the correctness of the compensated dataset. Wherein, the error term verification dataset is based on the measured uncorrected data (e.g. 6′) to be compensated with the error term (e.g. 4).

It should be noted that the verifications of the measured uncorrected data, the error term and the repeatability thereof in the above-described method for data verification are generally based on the various standard measurements performed by the main control unit of the test system. The following figures exemplarily show, but are not limited to, the various frequency response diagrams that allow an operator or a user to identify the standard measurements and check if the data is verified. Each of the frequency response diagrams is configured to be a graphical user interface displayed on the display of the control host of the main control unit.

For radio frequency (RF) characteristics measurements, the test system can measure frequency response characteristics in terms of S11 or S22 parameters over a concerned range of frequencies. Both S11 and S22 parameters can be used to indicate return loss and reflection coefficient of the RF facilities. The measurement can be made in a vector network analyzer (VNA), i.e., the analyzer of the test system of the present disclosure, in order to perform data transformation between a time domain and a frequency domain.

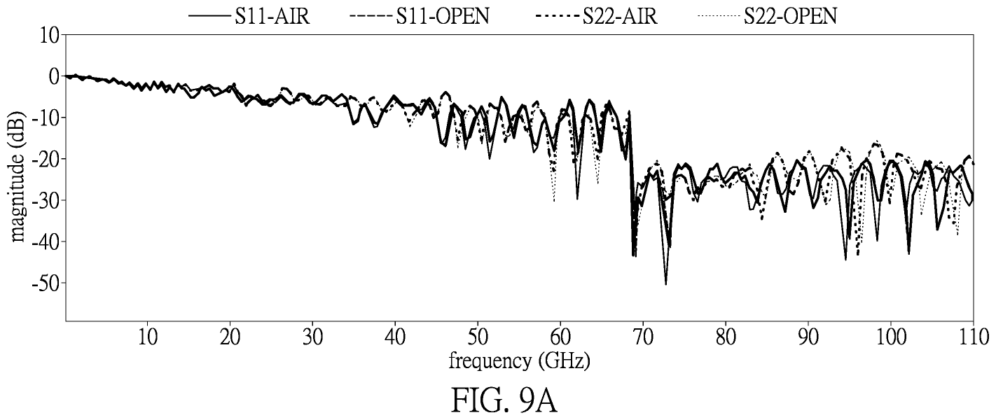

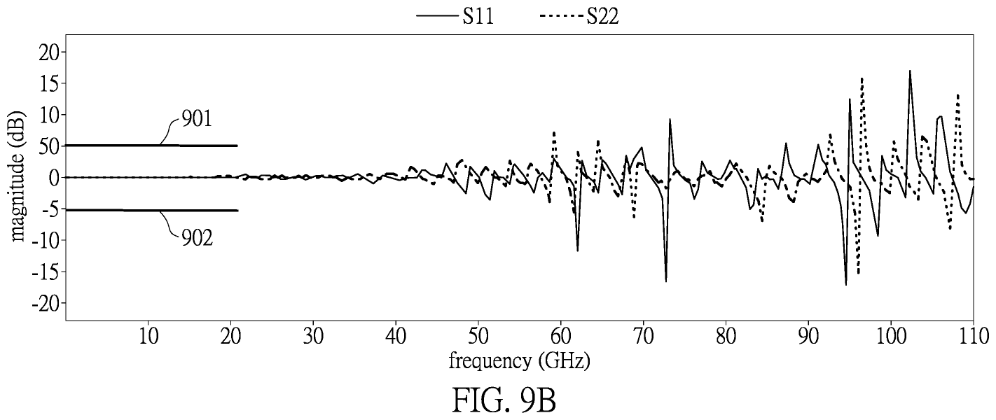

For example, reference is made to FIG. 9A, which shows a frequency reference diagram depicting non-normalized magnitudes of S11-AIR parameters, S11-OPEN parameters, S22-AIR parameters and S22-OPEN parameters, when the measurements are performed on the outputs (i.e., the uncorrected data) from an AIR testing circuit and an OPEN testing circuit of the calibration standard assembly.

Reference is next made to FIG. 9B, which is a schematic diagram of a frequency response diagram in normalized magnitude over frequencies. In FIG. 9B, the differences of S11 parameters that represent the normalized values of the differences of S11 parameters (i.e., S11-AIR, S11-OPEN shown in FIG. 9A) in AIR and OPEN standards is shown. Similarly, the differences of S22 parameters shown in FIG. 9B represent the normalized values of the differences of S22-AIR and S22-OPEN parameters of FIG. 9A.

Two boundary lines for the differences of S11 and S22 parameters with respect to AIR standard and OPEN standard magnitude measurements are provided according to one embodiment of the present disclosure. More specifically, a dash line depicted in the diagram shows a difference of S11 parameter with respect to AIR standard and OPEN standard magnitude measurement, and a solid line shows a difference of S22 parameter with respect to AIR standard and OPEN standard magnitude measurement.

According to the present frequency response diagram, a series of magnitude differences can be used to verify the measured uncorrected data as compared with a verification boundary setting. In the present diagram, a range between an upper-limit line 901 and a lower-limit line 902 being illustrated by a series of thresholds over frequencies forms the verification boundary setting.

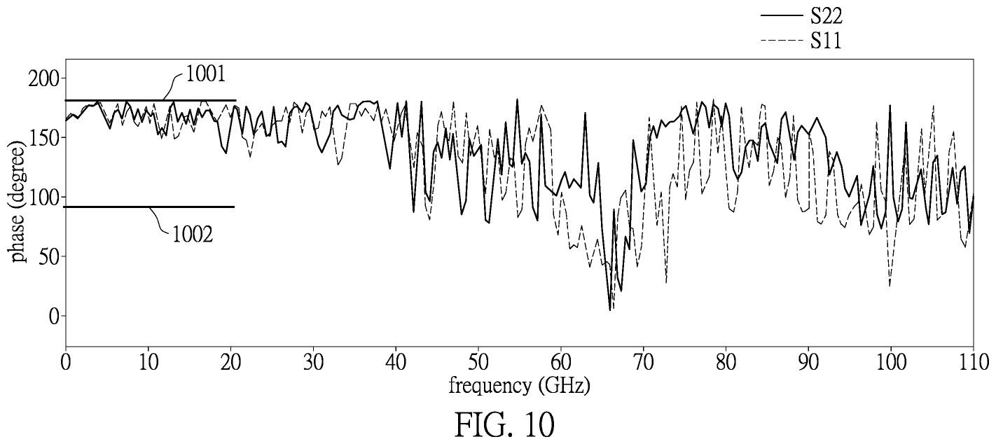

Reference is next made to FIG. 10, which is another schematic diagram of another frequency response diagram that depicts two differences of S11 and S22 parameters with respect to OPEN and SHORT standard measurements being illustrated in phases (which is normalized phases) over frequencies. There are two boundary lines including an upper-limit line 1001 and a lower-limit line 1002 for the differences of S11 and S22 parameters.

Accordingly, a series of S11 and S22 differences are calculated based on an OPEN-SHORT standard that can be used to verify the measured uncorrected data. The upper-limit line 1001 and the lower-limit line 1002 form a range that is configured to determine whether or not the measured uncorrected data can be verified.

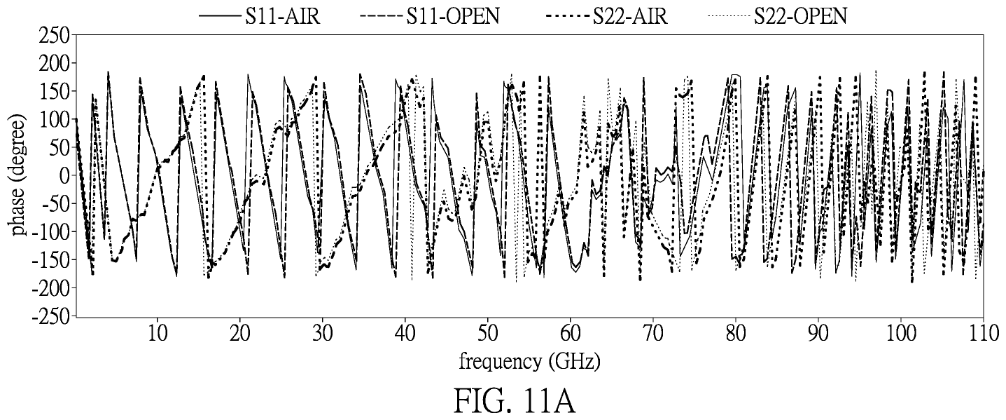

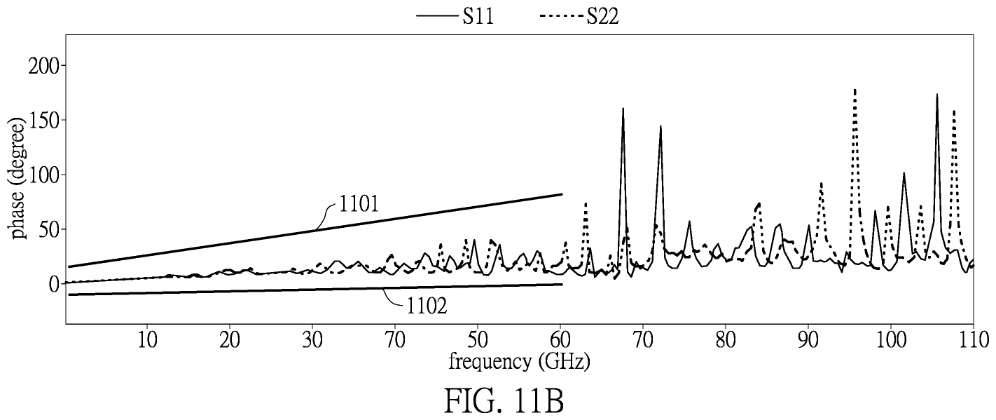

FIG. 11A shows a frequency reference diagram depicting non-normalized phases of S11-AIR parameters, S11-OPEN parameters, S22-AIR parameters and S22-OPEN parameters, when the measurements are performed on the outputs (i.e., the uncorrected data) from an AIR testing circuit and an OPEN testing circuit of the calibration standard assembly.

FIG. 11B shows a frequency response diagram that depicts two differences of S11 and S22 parameters being illustrated in normalized phases over frequencies with respect to AIR and OPEN standard measurements. A series of phase differences of S11 and S22 parameters are used to verify the measured uncorrected data. In the diagram, there are two boundary lines such as an upper-limit line 1101 around phase 90 and a lower-limit line 1102 around phase 0 provided for verifying the AIR standard and OPEN standard phase measurements.

Specifically, the differences of S11 parameters of FIG. 11B represent the normalized values of the differences of S11-AIR and S11-OPEN parameters shown in FIG. 11A. Similarly, the differences of S22 parameters of FIG. 11B represent the normalized values of the differences of S22-AIR and S22-OPEN parameters of FIG. 11A.

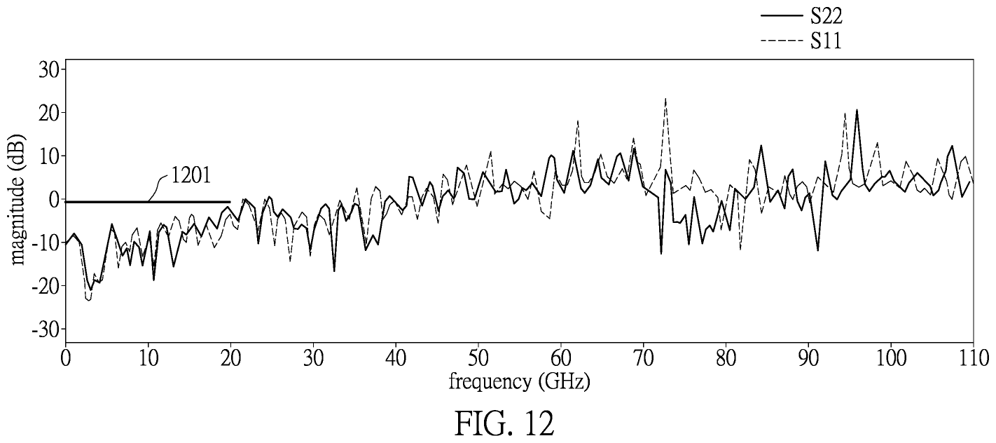

FIG. 12 shows another frequency response diagram that depicts two differences of S11 and S22 parameters with respect to OPEN and LOAD standard measurements when measuring the uncorrected data in magnitudes (which is normalized magnitudes) over frequencies that are respectively received from an OPEN testing circuit and a LOAD testing circuit of the calibration standard assembly.

In the present frequency response diagram, an upper limit 1201 forming a boundary line for OPEN standard and LOAD standard magnitude measurements can be provided for evaluating whether or not the measured uncorrected data is verified.

In particular, the above mentioned one or more boundary settings can be adjustable based on the practical circumstances. For example, the frequency response diagram shows the adjustable boundary line(s) on the graphical user interface and allows the user to adjust the boundary line(s) with an input method.

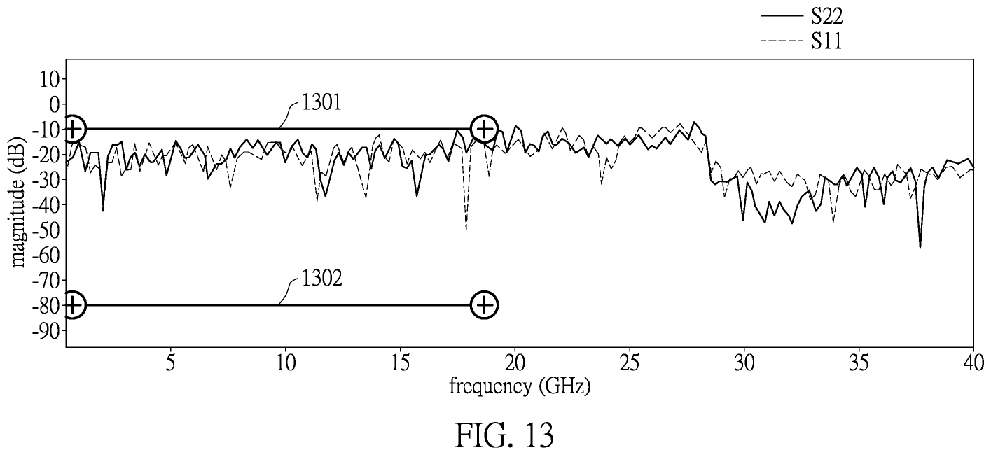

Reference is made to FIG. 13, which is a schematic diagram of a frequency response diagram that provides two adjustable boundary lines according to one embodiment of the present disclosure. It should be noted that the adjustable boundary lines also mean that the number of the boundary lines can be increased as required.

For example, in the diagram, an adjustable upper-limit line 1301 and another adjustable lower-limit line 1302 are provided. The user can adjust the boundary setting by moving the ends of the boundary lines shown on the graphical user interface. Furthermore, the user can also add one or more additional boundary lines on the diagram for the purpose of verifying the measured uncorrected data under a specific circumstance.

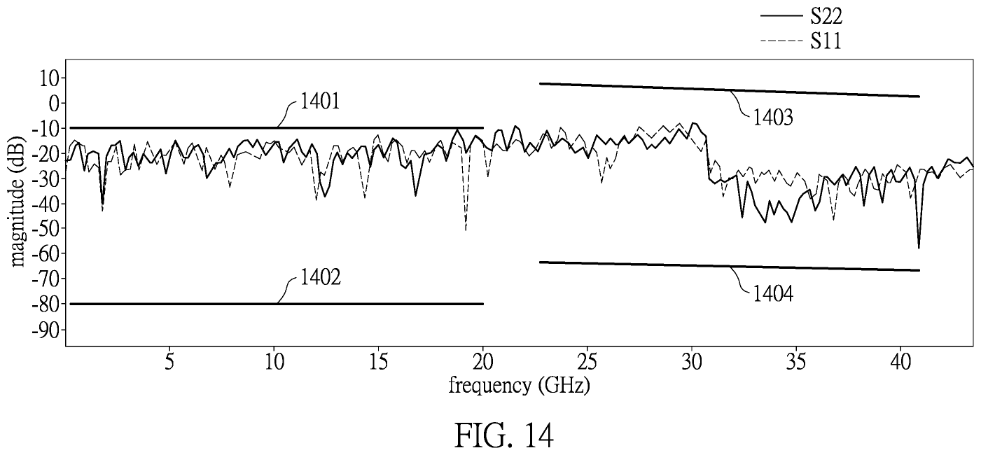

In FIG. 14, there are four boundary lines shown on the frequency response diagram. The four boundary lines are a first upper-limit line 1401, a first lower-limit line 1402, a second upper-limit line 1403 and a second lower-limit line 1404. The two upper-limit lines 1401 and 1403 are used to check the magnitude difference of S11 and S22 parameters at the upper limit with respect to two different testing circuits of different standards in two different frequency ranges. The two lower-limit lines 1402 and 1404 are used to check the magnitudes at the lower limit.

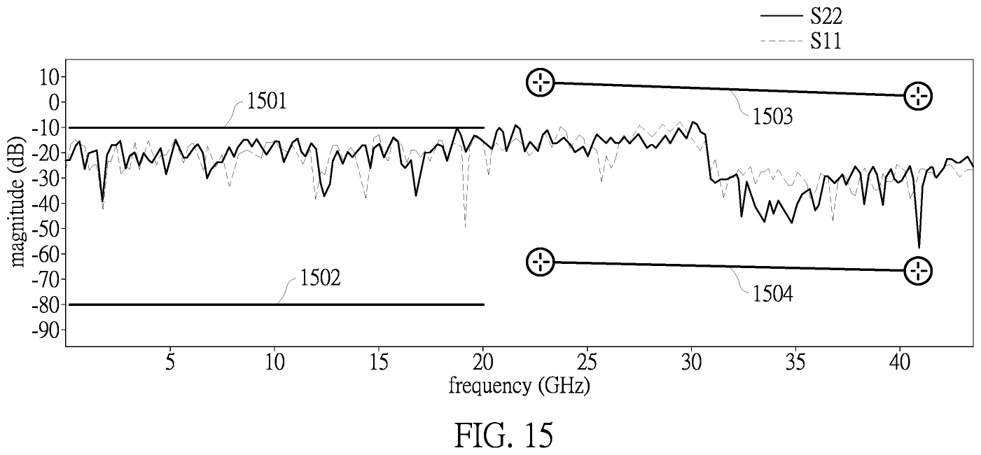

FIG. 15 shows another example of the frequency response diagram that provides two fixed boundary lines including a first upper-limit line 1501 and a first lower-limit line 1502 and two adjustable boundary lines including an adjustable second upper-limit line 1503 and an adjustable second lower-limit line 1504.

Besides the fixed boundary lines (1501, 1502), the frequency response diagram provides the adjustable second upper-limit line 1503 and the adjustable second lower-limit line 1504 that allow the user to adjust the upper and lower boundary lines within a second half of frequency range.

Accordingly, the measured uncorrected data can be verified if the differences of S11 and S22 parameters with respect to any two of the standard measurements are within the range defined by the limit lines (1501, 1502, 1503 and 1504) over frequencies. It should be noted that the verification boundary setting can be adjusted if it is necessary.

In conclusion, rather than the conventional test system that does not verify the correctness of the data in a calibration process and needs to repeat the whole calibration process when discovering an error, receiving the compensation value after an error term is calculated, the test system that performs the method for data verification of the present disclosure uses the data generated by the main control unit of the test system for calibration and required to be verified in order to guarantee correctness of the data. More, the method for data verification is to verify the raw data (i.e., the uncorrected data) outputted by the analyzer of the test system, the repeatability of the measured uncorrected data and the error term that is used to compensate the data outputted by the test system by several boundary settings. Accordingly, based on the data verification performed by the test system and the compensation made by the error term, the test system can obtain accurate electrical characteristics of the device under test through the probe assembly.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for data verification for a test system, comprising:
inputting, via a probe assembly of the test system, incident data from a main control unit of the test system to a calibration standard assembly having two or more testing circuits;
obtaining, by the main control unit, a measured uncorrected data by measuring the incident data through the two or more testing circuits; and
verifying the measured uncorrected data by performing relative comparison on any two sets of the measured uncorrected data outputted from at least two testing circuits of the calibration standard assembly;
wherein, one of the testing circuits is selected as a reference circuit and another one of the testing circuits is selected as a second testing circuit, so as to verify the measured uncorrected data outputted from the second testing circuit.

2. The method according to claim 1, wherein a result of the relative comparison is compared with a verification boundary setting for verifying the measured uncorrected data; wherein, before the measured uncorrected data is verified, the method further comprises a step of comparing the measured uncorrected data with a raw data boundary setting.

3. The method according to claim 2, wherein the verification boundary setting and the raw data boundary setting are respectively adjustable and illustrated by a series of thresholds over frequencies or a range between an upper-limit line and a lower-limit line over frequencies.

4. The method according to claim 1, wherein any of the two or more testing circuits mounted on a calibration substrate is configured to be contacted by one or more probe tips of at least one probe assembly of the test system.

5. The method according to claim 4, wherein the measured uncorrected data contains a series of frequency responses that relate to electrical characteristics of the probe assembly of the test system and are expressed in phases or magnitudes over frequencies.

6. The method according to claim 4, wherein the two or more testing circuits are selected from a group essentially consisting of an AIR testing circuit, an OPEN testing circuit, a SHORT testing circuit, a LOAD testing circuit, a THROUGH testing circuit and a LINE testing circuit; and the measured uncorrected data is produced based on a corresponding standard measurement which is selected from an AIR standard, an OPEN standard, a SHORT standard, a LOAD standard, a THROUGH standard and a LINE standard.

7. The method according to claim 1, wherein, before the steps of the method for data verification, repeatability verification is performed for testing stability of the test system and the repeatability verification includes steps of:
inputting, via the probe assembly of the test system, the data to the calibration standard assembly;
repeatedly measuring uncorrected data through the two or more testing circuits of the calibration standard assembly; and
verifying repeatability of the measured uncorrected data by comparing a difference between any two of the repeatedly-measured uncorrected data with a repeatability boundary setting.

8. The method according to claim 1, wherein the main control unit includes a control host that calculates a compensation data for compensating measurement of the control host by comparing an ideal dataset with the verified measured uncorrected data.

9. The method according to claim 8, wherein the compensation data is provided for compensating a next measured uncorrected data so as to obtain an error term verification dataset; and the compensation data is verified if a difference between the error term verification dataset and the ideal dataset is within a model data boundary setting.

10. A test system that performs a method for data verification thereof, comprising:
a main control unit including a control host and an analyzer;
a probe assembly including at least one probe-head having one or more probe tips and at least one cable linked to the analyzer;
wherein the probe assembly is configured to contact one of testing circuits of a calibration standard assembly via the one or more probe tips for performing a calibration process with an incident data generated by the control host;
wherein the test system performs the method for data verification by the control host, and the method comprises:
inputting, via the probe assembly of the test system, incident data from the main control unit of the test system to the calibration standard assembly having two or more testing circuits;
obtaining, by the control host, a measured uncorrected data by measuring the incident data through the two or more testing circuits; and
verifying the measured uncorrected data by performing relative comparison on any two sets of the measured uncorrected data outputted from at least two of the testing circuits of the calibration standard assembly;
wherein, one of the testing circuits is selected as a reference circuit and another one of the testing circuits is selected as a second testing circuit, so as to verify the measured uncorrected data outputted from the second testing circuit.

11. The test system according to claim 10, wherein a result of the relative comparison is compared with a verification boundary setting for verifying the measured uncorrected data; and the verification boundary setting is adjustable and illustrated by a series of thresholds over frequencies or a range between an upper-limit line and a lower-limit line over frequencies.

12. The test system according to claim 10, wherein the two or more testing circuits are selected from a group essentially consisting of an AIR testing circuit, an OPEN testing circuit, a SHORT testing circuit, a LOAD testing circuit, a THROUGH testing circuit and a LINE testing circuit; and the measured uncorrected data is produced based on a corresponding standard measurement which is selected from an AIR standard, an OPEN standard, a SHORT standard, a LOAD standard, a THROUGH standard and a LINE standard.

13. The test system according to claim 10, wherein, under a reflection mode, the analyzer processes signals received by at least one port via a signal terminal and a ground terminal of the at least one probe-head of the probe assembly; and, under a transmission mode, the analyzer processes the signals received by two or more ports via signal terminals and ground terminals of the at least one probe-head of the probe assembly.

14. The test system according to claim 10, wherein the measured uncorrected data contains a series of frequency responses that relate to electrical characteristics of the probe assembly of the test system and are expressed in phases or magnitudes over frequencies.

15. The test system according to claim 14, wherein the series of frequency responses are expressed by a frequency response diagram displayed on a display device of the main control unit, and a verification boundary setting used to verify the measured uncorrected data is illustrated by a series of threshold as a boundary line shown in the frequency response diagram over frequencies or a range between an upper-limit line and a lower-limit line shown in the frequency response diagram over frequencies.

16. The test system according to claim 15, wherein the boundary line, the upper-limit line and/or the lower-limit line is adjustable via a computer-implemented adjustment tool on the frequency response diagram.

17. The test system according to claim 16, wherein the boundary line, the upper-limit line and/or the lower-limit line has only one segment with a set of boundary values or has multiple segments with different sets of boundary values.

18. The test system according to claim 10, wherein, in the method for data verification, before the steps of the method for data verification, repeatability verification is performed for testing stability of the test system and the repeatability verification includes steps of:
inputting, via the probe assembly of the test system, the data to the calibration standard assembly;
repeatedly measuring uncorrected data through the two or more testing circuits of the calibration standard assembly; and
verifying repeatability of the measured uncorrected data by comparing a difference between any two of the repeatedly-measured uncorrected data with a repeatability boundary setting.

19. The test system according to claim 10, wherein, in the method for data verification, the control host calculates a compensation data that is used to compensate measurement of the control host by comparing an ideal dataset with the verified measured uncorrected data.

20. The test system according to claim 19, wherein the compensation data is provided for compensating a next measured uncorrected data so as to obtain an error term verification dataset; and the compensation data is verified if a difference between the error term verification dataset and the ideal dataset is within a model data boundary setting.
